(19) United States
(12) Patent Application Publication
(10) Pub. No.: US 2025/0180790 A1
(43) Pub. Date: Jun. 5, 2025

(54) PRISM AND OPTICAL DEVICE

(71) Applicant: FURUKAWA ELECTRIC CO., LTD., Tokyo (JP)

(72) Inventors: Atsushi KAJI, Tokyo (JP); Atsushi IZAWA, Tokyo (JP); Noritaka MATSUBARA, Tokyo (JP); Kazuya NAGASHIMA, Tokyo (JP); Yozo ISHIKAWA, Tokyo (JP)

(73) Assignee: FURUKAWA ELECTRIC CO., LTD., Tokyo (JP)

(21) Appl. No.: 19/047,703

(22) Filed: Feb. 7, 2025

Related U.S. Application Data
(63) Continuation of application No. PCT/JP2023/029285, filed on Aug. 10, 2023.

(30) Foreign Application Priority Data
Aug. 18, 2022 (JP) 2022-130582

(51) Int. Cl. G02B 5/04; G02B 27/10; G02B 27/12; H04B 10/40

(52) U.S. Cl. CPC G02B 5/04; G02B 27/1006; G02B 27/126; H04B 10/40

(57) ABSTRACT

A prism includes an incidence plane, a reflection plane and an output plane, and changes a direction of travel of light and has a refractive index of n where n>1. In a case where the prism is viewed in a first direction, an angular difference between the incidence plane and the output plane is 90 degrees, the light input to the incidence plane travels in a second direction, the incidence plane extends to be directed more in the second direction from a position where the light is input, toward the output plane, and the following Expression 1 is satisfied when an angular difference between a virtual plane orthogonal to the second direction and the incidence plane is θ where θ>0 degrees and an angular difference between the output plane and the reflection plane is x degrees.

45<x<45+2θ/n (1)

This application is a continuation of International Application No. PCT/JP2023/029285, filed on Aug. 10, 2023 which claims the benefit of priority of the prior Japanese Patent Application No. 2022-130582, filed on Aug. 18, 2022, the entire contents of which are incorporated herein by reference.

### BACKGROUND

The present disclosure relates to prisms and optical devices.

A known optical device includes a cube beam splitter that splits incident light in a rectilinear direction parallel to a direction of travel of the incident light, and a direction orthogonal to the rectilinear direction (for example, Japanese Unexamined Patent Application, Publication No. 2001-021775).

This type of cube beam splitter is generally made of two right-angled prisms bonded to each other. In this case, the two right-angled prisms have the same triangular prism shape with a cross section in a right-angled isosceles triangle shape. The cube beam splitter is made by surfaces being bonded to each other, the surfaces being surfaces of the two right-angled prisms and each being the hypotenuse in the cross section.

### SUMMARY

A cube beam splitter disclosed in Japanese Unexamined Patent Application, Publication No. 2001-021775 has an incidence plane orthogonal to incident light. An unwanted phenomenon may occur in this case, the unwanted phenomenon being that light reflected by the incidence plane is returned through a transmission path of the incident light, causing light interference or damage to an optical component, for example.

To address this problem, inclining the incidence plane to a direction orthogonal to the incident light enables the reflected light at the incidence plane to be deflected from the transmission path of the incident light, enabling the above mentioned unwanted phenomenon to be avoided.

However, in this case, light from the cube beam splitter is output in the rectilinear direction and an inclined direction inclined to the direction orthogonal to the rectilinear direction. Optical components that receive light output in an orthogonal direction from a cube beam splitter having an incidence plane orthogonal to incident light like in Japanese Unexamined Patent Application, Publication No. 2001-021775 are lined up in the orthogonal direction orthogonal to a rectilinear direction and are thus not positionally shifted in the rectilinear direction in relation to the cube beam splitter. By contrast, in the case where the light is output in the inclined direction from the cube beam splitter having the incidence plane inclined to the direction orthogonal to incident light, optical components that receive that light are not lined up in the inclined direction and the orthogonal direction and are thus shifted in the rectilinear direction in relation to the cube beam splitter. Therefore, an optical device including these cube beam splitter and optical components may increase in size in the rectilinear direction.

There is a need for a prism and an optical device that are novel and improved and that enable further downsizing.

According to one aspect of the present disclosure, there is provided a prism including: an incidence plane that is a plane extending in a first direction and is where light is input to; a reflection plane that is a plane extending in the first direction and is where at least part of the light that has been input to the incidence plane is reflected; and an output plane that is a plane extending in the first direction and is where the at least part of the light reflected by the reflection plane is output from, wherein the incidence plane, the reflection plane, and the output plane respectively extend in directions intersecting the first direction and different from one another, the prism changes a direction of travel of light approximately along a virtual plane orthogonal to the first direction and has a refractive index of n where n>1, and in a case where the prism is viewed in the first direction, an angular difference between the incidence plane and the output plane is 90 degrees, the light input to the incidence plane travels in a second direction, the incidence plane extends to be directed more in the second direction from a position where the light is input, toward the output plane, and the following Expression 1 is satisfied when an angular difference between a virtual plane orthogonal to the second direction and the incidence plane is θ where θ>0 degrees and an angular difference between the output plane and the reflection plane is x degrees.

$$45 < x < 45 + 2 θ / n \qquad ( 1 )$$

According to another aspect of the present disclosure, there is provided a prism including: an incidence plane that is a plane extending in a first direction and is where light is input to; a reflection plane that is a plane extending in the first direction and is where at least part of the light that has been input to the incidence plane is reflected; and an output plane that is a plane extending in the first direction and is where the at least part of the light reflected by the reflection plane is output from, wherein the incidence plane, the reflection plane, and the output plane respectively extend in directions intersecting the first direction and different from one another, the prism changes a direction of travel of light approximately along a virtual plane orthogonal to the first direction and has a refractive index of n where n>1, and in a case where the prism is viewed in the first direction, an angular difference between the incidence plane and the output plane is 90 degrees, the light input to the input plane travels in a second direction, the incidence plane extends to be directed more in a direction opposite to the second direction from a position where the light is input, toward the output plane, and the following Expression 2 is satisfied when an angular difference between a virtual plane orthogonal to the second direction and the incidence plane is θ where θ>0 degrees and an angular difference between the output plane and the reflection plane is y degrees.

$$45 - 2 θ / n < y < 45 \qquad ( 2 )$$

### BRIEF DESCRIPTION OF THE DRAWINGS

FIG. 1 is an exemplary and schematic plan view of a prism according to a first embodiment;

FIG. 2 is a plan view of a known prism that is a reference example;

FIG. 3 is an exemplary and schematic plan view of an optical device including the prism according to the first embodiment;

FIG. 4 is a plan view of an optical device including the known prism that is the reference example;

FIG. 5 is an exemplary and schematic plan view of a prism according to a second embodiment;

FIG. 6 is an exemplary and schematic plan view of an optical device including the prism according to the second embodiment;

FIG. 7 is a plan view of a reference example that is an optical device including a known prism that is different from that in FIG. 2;

FIG. 8 is an exemplary and schematic plan view of an optical device according to a third embodiment;

FIG. 9 is an exemplary and schematic plan view of an optical device according to a fourth embodiment;

FIG. 10 is an exemplary and schematic plan view of an optical device according to a fifth embodiment;

FIG. 11 is an exemplary and schematic plan view of an optical device according to a sixth embodiment;

FIG. 12 is an exemplary and schematic plan view of a prism according to a seventh embodiment;

FIG. 13 is an exemplary and schematic plan view of an optical device according to an eighth embodiment; and

FIG. 14 is an exemplary and schematic plan view of an optical device according to a ninth embodiment.

### DETAILED DESCRIPTION

Exemplary embodiments of the present disclosure will be disclosed hereinafter. Configurations of the embodiments and functions and effects brought about by these configurations described hereinafter are just examples. The present disclosure may be implemented by any configuration other than those disclosed hereinafter with respect to the embodiments. Furthermore, the present disclosure achieves at least one of various effects (including derivative effects) achieved by these configurations.

The plural embodiments described hereinafter include like components. Therefore, the configurations of these embodiments achieve like functions and effects based on the like components. The same reference sign will hereinafter be assigned to such like components and any redundant description thereof may be omitted.

The drawings are schematic and dimensions therein may be different from the actual dimensions. In each drawing, a direction X is indicated by an arrow X, a direction Y by an arrow Y, and a direction Z by an arrow Z. The direction X, the direction Y, and the direction Z intersect one another and are orthogonal to one another. In the drawings, optical paths are represented by broken lines.

Ordinals are assigned for convenience to distinguish between directions and components in this specification, but are not to limit any priority, order, or number of components, for example.

### First Embodiment

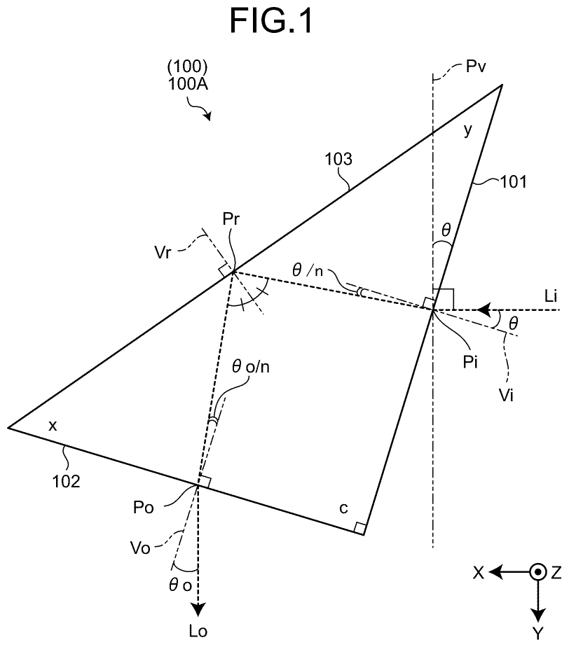

FIG. 1 is a plan view of a prism 100A (100) according to a first embodiment, the prism 100A being viewed in a direction opposite to the direction Z. The prism 100 is made of, for example, a silica-based glass material. The prism 100 has a refractive index n larger than 1.

The prism 100 has an incidence plane 101, an output plane 102, and a reflection plane 103. Light input to the prism 100 from an incidence position Pi on the incidence plane 101 is reflected at a reflection position Pr on the reflection plane 103 and is output outside the prism 100 from an output position Po on the output plane 102. In the prism 100, a traveling direction of incident light Li on the incidence plane 101 is the direction X and a traveling direction of output light Lo from the output plane 102 is the direction Y.

The incidence plane 101, the output plane 102, and the reflection plane 103 are each a plane extending in the direction Z. The incidence plane 101, the output plane 102, and the reflection plane 103 respectively extend in directions different from one another, the directions intersecting the direction Z. The incidence plane 101 and the output plane 102 are orthogonal to each other, and the incidence plane 101, the output plane 102, and the reflection plane 103 form a right-angled triangle in a planar view of FIG. 1. That is, the prism 100 has a triangular prism shape extending in the direction Z.

However, in this embodiment, a side corresponding to the incidence plane 101 and a side corresponding to the output plane 102 have lengths different from each other in the planar view. That is, a cross section of the prism 100 has a right-angled triangle shape but not a right-angled isosceles triangle shape, the cross section being orthogonal to the direction Z. Therefore, in the planar view, an angle c between the incidence plane 101 and the output plane 102 is 90°, and an angle x between the output plane 102 and the reflection plane 103 and an angle y between the incidence plane 101 and the reflection plane 103 are different from each other and both larger than 0° and smaller than 90°. In this embodiment, the angle x is larger than the angle y. The direction Z is an example of a first direction.

The incidence plane 101 is inclined, by an angle θ, to a virtual orthogonal plane Pv orthogonal to the traveling direction (direction X) of the incident light Li on the incidence plane 101. In this embodiment, the incidence plane 101 extends to be directed more in the direction X from the incidence position Pi of the incident light Li, toward the output plane 102. Therefore, light reflected at the incidence plane 101 does not head in a direction opposite to the direction X, the light being part of the incident light Li. That is, the reflected light travels in a direction deflected to be directed more in the direction Y from a transmission path of the incident light Li. The unwanted phenomenon due to the reflected light from the incidence plane 101 returning to the transmission path of the incident light Li is thereby able to be avoided. The direction X is an example of a second direction. In this case, an incident angle is θ.

The incident angle θ and a refraction angle at the incidence position Pi are angles of traveling directions of light to a perpendicular line Vi to the incidence plane 101 at the incidence position Pi. From Snell's Law, the refraction angle at the incidence position Pi is θ/n in relation to the incident angle θ when sin θ≈θ.

Light travels along a path represented by a broken line from the incidence position Pi and reaches the reflection plane 103. An incident angle and a reflection angle at the reflection position Pr are angles of traveling directions of light to a perpendicular line Vr to the reflection plane 103 at the reflection position Pr. The incident angle and reflection angle at the reflection position Pr are the same.

The light travels along the path represented by the broken line from the reflection position Pr and reaches the output plane 102. At the output position Po, an incident angle and an output angle do that is a refraction angle are angles of traveling directions of light to a perpendicular line Vo to the output plane 102 at the output position Po. From Snell's Law, the incident angle at the output position Po is θo/n in relation to the output angle θo when sin θ≈θ.

In the case of FIG. 1, for the incident angle θo/n (in degrees) at the output position Po, the following Equation 10 holds geometrically.

$$2 x - θ / n = θ o / n + 90 \qquad ( 10 )$$

When θo=θ, the incident light Li and the output light Lo are orthogonal to each other. Therefore, solving Equation 10 for x when θo=θ results in the following Equation 1-1.

$$x = 45 + θ / n \qquad ( 1 - 1 )$$

That is, when the angle x (in degrees) between the output plane 102 and the reflection plane 103 is 45+θ/n, the incident light Li and the output light Lo are orthogonal to each other.

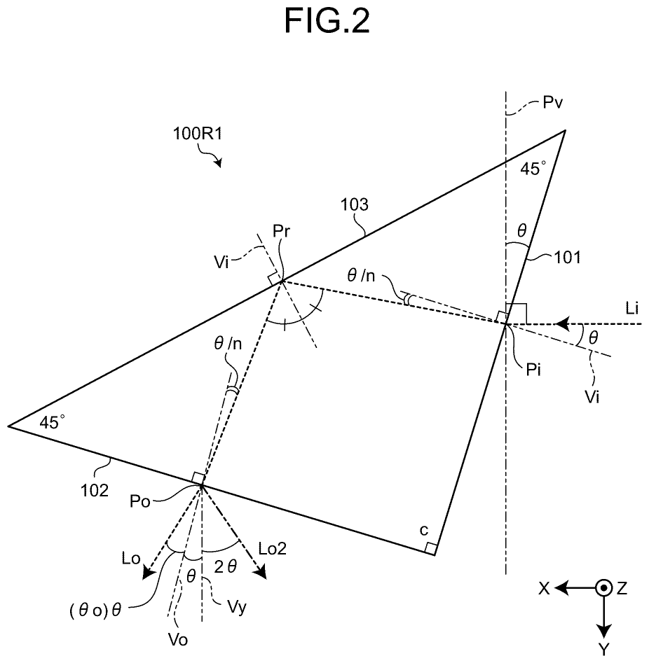

FIG. 2 is a plan view of a prism 100R1 viewed in the direction opposite to the direction Z, the prism 100R1 being a reference example and a known so-called right-angled prism having a right-angled isosceles triangle shape in a planar view. As illustrated in FIG. 2, in a case where an incidence plane 101 is inclined, by an angle θ, to a virtual orthogonal plane Pv orthogonal to a traveling direction (direction X) of incident light Li on the incidence plane 101 and extends to be directed more in the direction X from an incidence position Pi, toward an output plane 102, an output angle at an output position Po is θ. Furthermore, an angle between a perpendicular line Vo to the output position Po and a virtual line Vy extending in the direction Y at the output position Po is θ. Therefore, an angle between a traveling direction of output light Lo and the direction Y is 20.

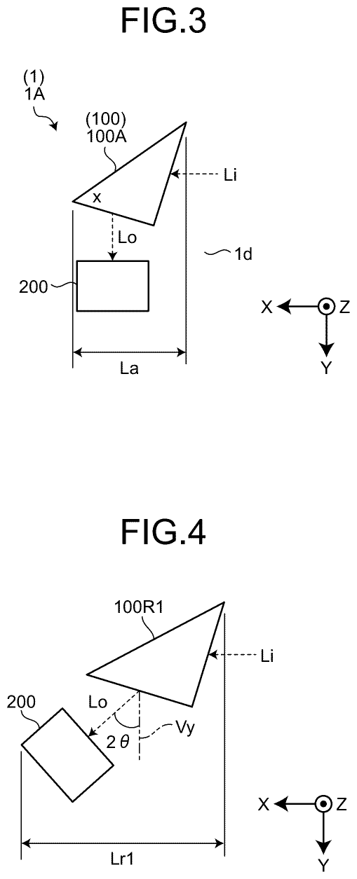

FIG. 3 is a plan view of part of an optical device 1A (1) including the prism 100A (100) according to the first embodiment, an optical component 200, and a base 1d. FIG. 4 is a plan view of part of an optical device including the prism 100R1 that is the reference example in FIG. 2, and the optical component 200. The output light Lo is input to or travels through the optical component 200. The base 1d supports the prism 100 and the optical component 200. In other words, the prism 100 and the optical component 200 are fixed to the base 1d.

As illustrated in FIG. 3, from the prism 100 in the optical device 1A (1) according to the first embodiment, the output light Lo travels in the direction Y orthogonal to the direction X that is the traveling direction of the incident light Li. Therefore, the prism 100 and the optical component 200 are lined up in the direction Y.

By contrast, in the case of FIG. 4, from the prism 100R1, the output light Lo travels in a direction inclined by 2θ in the direction X, to the direction Y. Therefore, the prism 100R1 and the optical component 200 are not lined up in the direction Y and are lined up in the traveling direction of the output light Lo, that is, the direction inclined by 2θ in the direction X to the direction Y.

As evident from comparison between FIG. 3 and FIG. 4, a length La in the direction X of an area occupied by the prism 100 and the optical component 200 in a layout (FIG. 3) according to the embodiment is shorter than a length Lr1 in the direction X of an area occupied by the prism 100R1 and the optical component 200 in a layout (FIG. 4) of the reference example. That is, this embodiment enables the optical device 1A (1) to be configured smaller by enabling a length of the optical device 1A (1) to be shorter than that of the reference example, the length being in the direction X.

From the above discussion, it can be understood that the length La in the direction X of the area occupied by the prism 100 and the optical component 200 is able to be made shorter than that of the known configuration in FIG. 2, in a case where the angle x (in degrees) between the output plane 102 and the reflection plane 103 is larger than 45° in the configuration, in which the incidence plane 101 is inclined, by the angle θ, to the virtual orthogonal plane Pv orthogonal to the traveling direction (direction X) of the incident light Li on the incidence plane 101 and extends to be directed more in the direction X from the incidence position Pi, toward the output plane 102.

Furthermore, in the known configuration in FIG. 2, the output angle θo is θ and the output light Lo is shifted in the direction X by 2θ from the virtual line Vy. It can be said that even in a case where a shift of output light Lo2 from the virtual line Vy in the direction opposite to the direction X is less than 2θ as illustrated in FIG. 2, the length La in the direction X of the area occupied by the prism 100 and the optical component 200 is able to be made shorter than that of the known configuration in FIG. 2. In a case where the shift of the output light Lo2 in the direction opposite to the X direction from the virtual line Vy is 2θ, the output angle θo is −3θ and substituting θo=−3θ in Equation 10 results in the following Equation 11 and then the following Equation 12.

$$2 x - θ / n = 3 θ / n + 90 \qquad ( 11 )$$

$$x = 45 + 2 θ / n \qquad ( 12 )$$

Therefore, it can be said that in a case where the following Expression 1 is satisfied, the length La in the direction X of the area occupied by the prism 100 and the optical component 200 is able to be made shorter than that of the known configuration having the right-angled prism in FIG. 2.

$$45 < x < 45 + 2 θ / n \qquad ( 1 )$$

Expression 1 and Equation 1-1 also hold for a prism that is a mirror image of the prism 100A according to the first embodiment.

### Second Embodiment

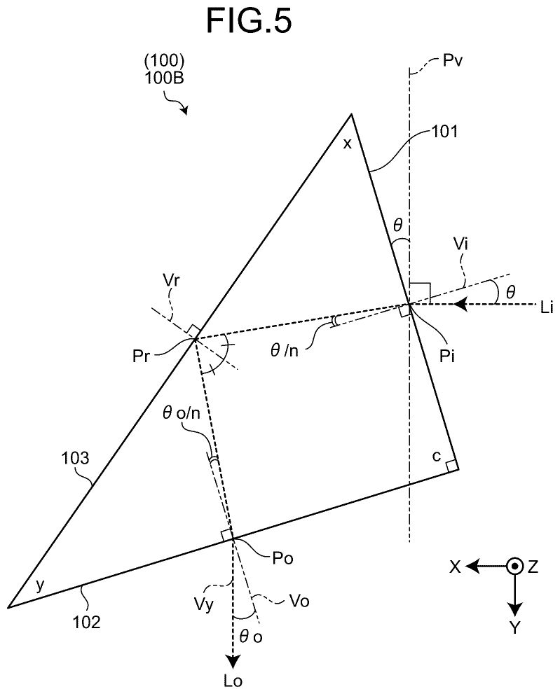

FIG. 5 is a plan view of a prism 100B (100) according to a second embodiment, the prism 100B being viewed in the direction opposite to the direction Z. In a planar view, an angle c between an incidence plane 101 and an output plane 102 is 90°, and an angle y between the output plane 102 and a reflection plane 103 and an angle x between the incidence plane 101 and the reflection plane 103 are different from each other and both larger than 0° and smaller than 90°. In this embodiment also, the angle x is larger than the angle y.

As evident from comparison between FIG. 5 and FIG. 1, it can be said that the prism 100B according to this embodiment is a mirror image of the prism 100A according to the first embodiment and light travels in a direction opposite to that in the first embodiment. It can be said that in the second embodiment, the incidence plane 101 is configured to be inclined, by an angle θ, to a virtual orthogonal plane Pv orthogonal to a traveling direction (direction X) of incident light Li on the incidence plane 101 and to extend to be directed more in the direction opposite to the direction X from an incidence position Pi, toward the output plane 102.

In this embodiment, the following Equation 20 holds geometrically for an incident angle θo/n (in degrees) at an output position Po.

$$2 y + θ / n = 90 - θ o / n \qquad ( 20 )$$

When θo=θ, the incident light Li and the output light Lo are orthogonal to each other. Therefore, solving Equation 20 for y when θo=θ results in the following Equation 2-1.

$$Y = 45 - θ / n \qquad ( 2 - 1 )$$

That is, when the angle x (in degrees) between the output plane 102 and the reflection plane 103 is 45+θ/n, the incident light Li and the output light Lo are orthogonal to each other.

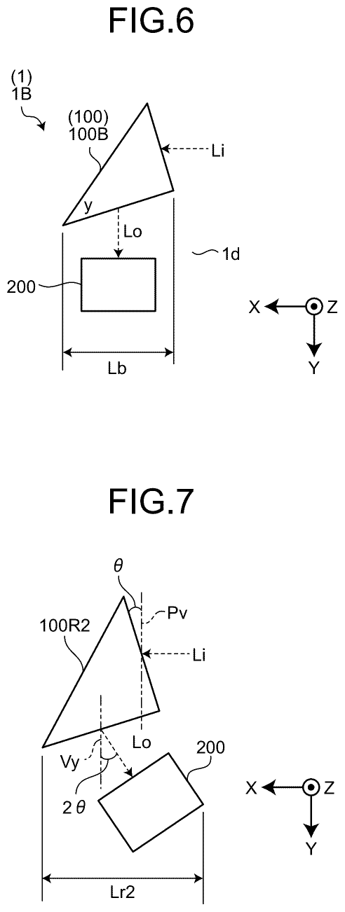

FIG. 6 is a plan view of part of an optical device 1B (1) including the prism 100B (100) according to the second embodiment, an optical component 200, and a base 1d. FIG. 7 is a plan view of a reference example that is part of an optical device including a prism 100R2 and an optical component 200.

As illustrated in FIG. 6, from the prism 100 in the optical device 1B (1) according to the second embodiment, the output light Lo travels in the direction Y orthogonal to the direction X that is the traveling direction of the incident light Li. Therefore, the prism 100 and the optical component 200 are lined up in the direction Y.

By contrast, in the case of FIG. 7, from the prism 100R2, output light Lo travels in a direction inclined to the direction Y by 2θ in the direction opposite to the direction X. Therefore, the prism 100R2 and the optical component 200 are not lined up in the direction Y and are lined up in the traveling direction of the output light Lo, that is, the direction inclined to the direction Y by 2θ in the direction opposite to the direction X.

As evident from comparison between FIG. 6 and FIG. 7, a length Lb in the direction X of an area occupied by the prism 100 and the optical component 200 in a layout (FIG. 6) according to this embodiment is shorter than a length Lr2 in the direction X of an area occupied by the prism 100R2 and the optical component 200 in a layout (FIG. 7) of the reference example. That is, this embodiment enables the optical device 1B (1) to be configured smaller by enabling a length of the optical device 1B (1) to be shorter than that of the reference example, the length being in the X-direction. That is, the second embodiment also achieves effects similar to those of the first embodiment.

In a known prism having a right-angled isosceles triangle shape in a planar view, y=45 (in degrees), and as illustrated in FIG. 7, the output light Lo is shifted in the direction opposite to the direction X by 2θ from a virtual line Vy extending in the direction Y. On the other hand, in a case where the output light Lo is shifted in the direction X by 2θ from the virtual line Vy, an output angle θo is 3θ and substituting θo=3θ in Equation 20 results in the following Equation 21 and then the following Equation 22.

$$2 y + θ / n = 90 - 3 θ / n \qquad ( 21 )$$

$$y = 45 - 2 θ / n \qquad ( 22 )$$

Therefore, in a case where the following Expression 2 is satisfied, the length Lb in the direction X of the area occupied by the prism 100 and the optical component 200 is able to be made shorter than that of the known configuration having the right-angled prism in FIG. 2.

$$45 - 2 θ / n < y < 45 \qquad ( 2 )$$

Expression 2 and Equation 2-1 also hold for a prism that is a mirror image of the prism 100B according to the second embodiment.

### Third Embodiment

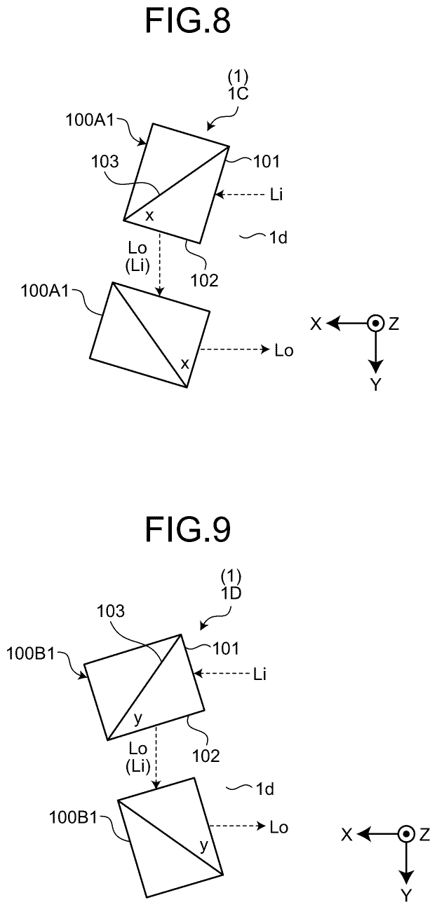

FIG. 8 is a plan view of an optical device 1C (1) according to a third embodiment. As illustrated in FIG. 8, in this embodiment, the optical device 1C (1) includes plural cube prisms 100A1. The cube prisms 100A1 are each manufactured by bonding surfaces of the prisms 100A (100) according to the first embodiment to each other, the surfaces being the hypotenuses in the planar view.

In this case, the cube prisms 100A1 each achieve functions and effects similar to those of the prism 100A (100) according to the first embodiment. That is, incident light Li and output light Lo on and from each of the cube prisms 100A1 are orthogonal to each other. Therefore, the incident light Li on the cube prism 100A1 positioned at the top in FIG. 8 and the output light Lo from the cube prism 100A1 positioned at the bottom in FIG. 8 are antiparallel to each other, that is, parallel and directed oppositely to each other. This configuration enables the optical device 1C (1) to be configured smaller in the direction X and the direction Y. In this example, the cube prism 100A1 upstream (at the top in FIG. 8) is an example of a first prism, and the cube prism 100A1 downstream (at the bottom in FIG. 8) is an example of a second prism.

### Fourth Embodiment

FIG. 9 is a plan view of an optical device 1D (1) according to a fourth embodiment. As illustrated in FIG. 9, in this embodiment, the optical device 1D (1) includes plural cube prisms 100B1. The cube prisms 100B1 are each manufactured by bonding surfaces of the prisms 100B (100) according to the second embodiment to each other, the surfaces being the hypotenuses in the planar view.

In this case, the cube prisms 100B1 each achieve functions and effects similar to those of the prism 100B (100) according to the second embodiment. That is, incident light Li and output light Lo on and from each of the cube prisms 100B1 are orthogonal to each other. Therefore, the incident light Li on the cube prism 100B1 positioned at the top in FIG. 9 and the output light Lo from the cube prism 100B1 positioned at the bottom in FIG. 9 are antiparallel to each other. This configuration enables the optical device 1D (1) to be configured smaller in the direction X and the direction Y. In this example, the cube prism 100B1 upstream (at the top in FIG. 9) is an example of the first prism, and the cube prism 100B1 downstream (at the bottom in FIG. 9) is an example of the second prism.

### Fifth Embodiment

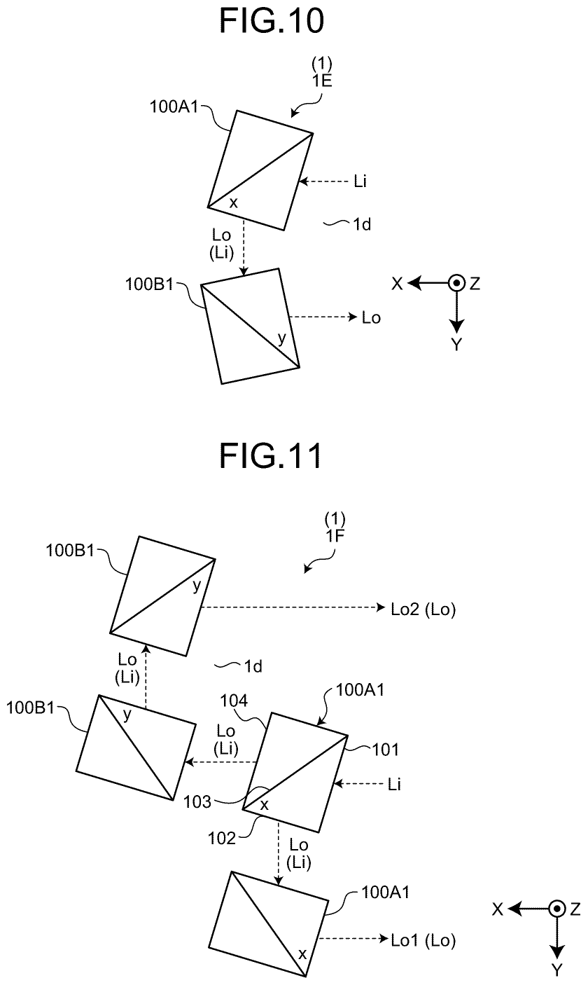

FIG. 10 is a plan view of an optical device 1E (1) according to a fifth embodiment. As illustrated in FIG. 10, in this embodiment, the optical device 1E (1) includes the same cube prism 100A1 as the third embodiment and the same cube prism 100B1 as the fourth embodiment.

In this case, the cube prisms 100A1 and 100B1 respectively achieve functions and effects similar to those of the prism 100A (100) according to the first embodiment and the prism 100B (100) according to the second embodiment. That is, incident light Li and output light Lo on and from the cube prism 100A1 are orthogonal to each other and incident light Li and output light Lo on and from the cube prism 100B1 are orthogonal to each other. Therefore, the incident light Li on the cube prism 100A1 positioned at the top in FIG. 10 and the output light Lo from the cube prism 100B1 positioned at the bottom in FIG. 10 are antiparallel to each other. This configuration enables the optical device 1E (1) to be configured smaller in the direction X and the direction Y. In this example, the cube prism 100A1 upstream (at the top in FIG. 10) is an example of the first prism, and the cube prism 100B1 downstream (at the bottom in FIG. 10) is an example of the second prism.

### Sixth Embodiment

FIG. 11 is a plan view of an optical device 1F (1) according to a sixth embodiment. As illustrated in FIG. 11, in this embodiment, the optical device 1F (1) includes the same cube prisms 100A1 as the third embodiment and the same cube prisms 100B1 as the fourth embodiment.

Furthermore, the cube prism 100A1 positioned in the middle in FIG. 11 function as a beam splitter. That is, its reflection plane 103 reflects part of light that has reached the reflection plane 103 and also transmits part of the light therethrough. Therefore, from this cube prism 100A1, output light Lo that has been transmitted through the reflection plane 103 and is output in the direction X from its output plane 104 on a side opposite to its incidence plane 101 and output light Lo that has been reflected at the reflection plane 103 and is output in the direction Y from its output plane 102 adjacent to the incidence plane 101 are output.

In this case also, the cube prisms 100A1 and 100B1 respectively achieve functions and effects similar to those of the prism 100A (100) according to the first embodiment and the prism 100B (100) according to the second embodiment. That is, incident light Li and output light Lo on and from each of the cube prisms 100A1 are orthogonal to each other and incident light Li and output light Lo on and from each of the cube prisms 100B1 are orthogonal to each other. Therefore, the incident light Li on the cube prism 100A1 positioned in the middle in FIG. 11 and output light Lo1 (Lo) from the cube prism 100A1 positioned at the bottom in FIG. 11 are antiparallel to each other. Furthermore, the incident light Li on the cube prism 100A1 positioned in the middle in FIG. 11 and output light Lo2 (Lo) from the cube prism 100B1 positioned at the top in FIG. 11 are antiparallel to each other. Therefore, the output light Lo1 and the output light Lo2 are parallel to each other. This configuration enables the optical device 1F (1) to be configured smaller in the direction X and the direction Y. In this example, the cube prism 100A1 upstream (in the middle in FIG. 11) is an example of the first prism and the other cube prisms 100A1 and 100B1 are each an example of the second prism. A combination of a plurality of the cube prisms 100A1 and 100B1 is not to be limited to the examples in FIG. 8 to FIG. 11. Furthermore, the prism 100A (see FIG. 1) and the prism 100B (see FIG. 5) may be applicable to the examples in FIG. 8 to FIG. 11, in place of the cube prisms 100A1 and 100B1.

### Seventh Embodiment

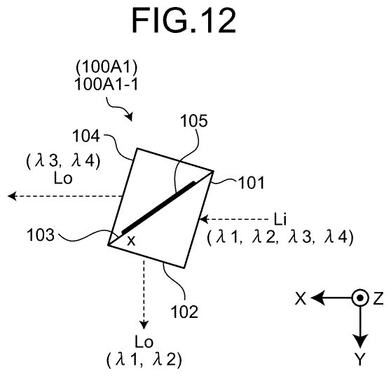

FIG. 12 is a plan view of a cube prism 100A1-1 (100A1) according to a seventh embodiment. In this embodiment, similarly to the cube prism 100A1 in the middle of FIG. 11, the cube prism 100A1-1 is manufactured by bonding surfaces of the prisms 100A (100) according to the first embodiment to each other, the surfaces being the hypotenuses in the planar view.

However, in this embodiment, a wavelength filter 105 is provided on their reflection planes 103. Therefore, in a case where the wavelength filter 105 reflects light having wavelengths λ1 and λ2 and transmits light having wavelengths λ3 and λ4 therethrough, for example, output light Lo from an output plane 104 on a side opposite to an incidence plane 101 includes light having the wavelengths λ3 and λ4 and output light Lo from an output plane 102 adjacent to the incidence plane 101 includes light having the wavelengths λ1 and λ2.

In this case also, incident light Li and the output light Lo from the output plane 104 are parallel to each other and the incident light Li and the output light Lo from the output plane 102 are orthogonal to each other. Therefore, an effect thereby achieved is that an optical device having the cube prism 100A1-1 (100A1) according to this embodiment is able to be downsized further.

### Eighth Embodiment

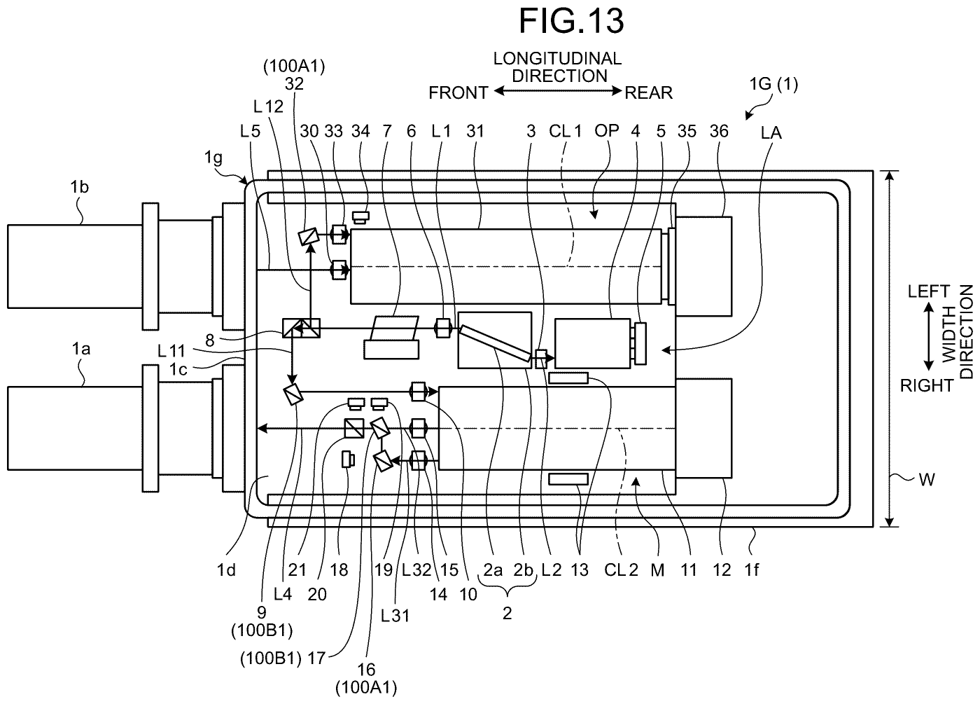

FIG. 13 is a plan view illustrating an internal configuration of an optical device 1G (1) according to an eighth embodiment and the plan view has been viewed from the top in a state where an upper lid portion 1e has been removed. The optical device 1G includes a housing 1g having a signal light output port 1a, a signal light input port 1b, a side wall portion 1c, a base 1d, the upper lid portion 1e, and a terminal portion 1f.

As illustrated in FIG. 13, the terminal portion 1f protrudes inside and outside from the optical device 1G. The terminal portion 1f is made of an insulating material and has a wiring pattern formed on a surface of and inside the terminal portion 1f, the wiring pattern being made of a conductor. The wiring pattern of the terminal portion 1f is electrically connected to a controller that is provided outside the optical device 1G and that controls operation of the optical device 1G. The controller is configured to include, for example, an integrated circuit (IC).

The optical device 1G has components housed therein, the components including: a chip-on-submount 2; a lens 3; a wavelength locker 4 that is a wavelength detector; a photodiode (PD) array 5; a lens 6; an optical isolator 7; a beam splitter 8; a mirror 9; a lens 10; a modulator 11; a modulator driver 12; a terminator 13; lenses 14 and 15; a beam splitter 16; a polarization beam combiner 17; monitor PDs 18 and 19; a beam splitter 20; and a monitor PD 21. The optical device 1G has further components housed therein, the further components including: a lens 30; a coherent mixer 31; a mirror 32; a lens 33; a monitor PD 34; a balanced PD array 35; and a transimpedance amplifier (TIA) 36.

These components are mounted in the housing 1g of the optical device 1G and the upper lid portion 1e is attached for hermetic sealing. Furthermore, these components excluding the modulator driver 12 and the TIA 36 are mounted on a base or temperature adjusting element arranged inside the housing 1g. The modulator driver 12 and the TIA 36 are mounted on the terminal portion 1f.

The optical device 1G is configured as an optical transceiver where output signal light is output from the signal light output port 1a that is an optical output unit and input signal light is input from the signal light input port 1b that is an optical input unit. Configurations and functions of these components will be described hereinafter.

### Optical Transmitter

Configurations and functions of components that function as an optical transmitter will be described first.

The chip-on-submount 2 includes a laser element 2a, and a submount 2b having the laser element 2a mounted thereon. The laser element 2a is, for example, a wavelength-tunable laser element. The submount 2b is made of a material high in thermal conductivity and efficiently radiates heat generated by the laser element 2a to the base where the submount 2b is mounted.

Electric power is supplied to the laser element 2a through the wiring pattern formed on the terminal portion 1f and the laser element 2a outputs laser light L1 of continuous waves (CWs) from a front end face of the laser element 2a longitudinally forward, the laser light L1 having been linearly polarized, the front end face being positioned longitudinally forward. Furthermore, the laser element 2a outputs laser light L2 for wavelength locking from a rear end face of the laser element 2a longitudinally rearward.

The lens 3 condenses the laser light L2 and inputs the condensed laser light L2 to the wavelength locker 4. The wavelength locker 4 is, for example, a publicly known wavelength locker including a planar lightwave circuit (PLC). The wavelength locker 4 splits the laser light L2 into three parts, outputs one of the three parts to the PD array 5, and outputs the other two parts to the PD array 5 after allowing the other two parts to pass through two filters respectively, the two filters periodically changing in transmissivity for wavelength and having wavelength discrimination properties. The two filters each include, for example, a ring resonator or an etalon filter and have transmission-wavelength characteristics different from each other.

The PD array 5 is configured to have three PDs arranged in an array. The three PDs of the PD array 5 respectively receive the three parts of the laser light output by the wavelength locker 4 and outputs electric current signals corresponding to intensities of the received light. The electric current signals are transmitted to the controller through the wiring pattern formed on the terminal portion 1f and are used for detection and control of wavelengths of the laser light L1.

The laser element 2a and the wavelength locker 4 are arranged in a longitudinal direction. Furthermore, the laser element 2a and the wavelength locker 4 are arranged such that an output position of the laser light L2 input to the wavelength locker 4 and an input position of the laser light L2 approximately coincide with each other widthwise, the output position being on the laser element 2a, the input position being on the wavelength locker 4. The laser element 2a and the wavelength locker 4 form a laser assembly LA.

The lens 6 collimates the laser light L1 and outputs the collimated laser light L1 to the optical isolator 7. The optical isolator 7 allows the laser light L1 to pass therethrough toward the beam splitter 8 and prevents passage of light that has traveled from the beam splitter 8. The optical isolator 7 thereby prevents any reflected light from entering the laser element 2a.

The beam splitter 8 splits the laser light L1 that has passed through the optical isolator 7, into laser light L11 and laser light L12. The laser light L11 travels rightward widthwise, and the laser light L12 travels leftward widthwise. The laser light L12 will be described in detail later.

The mirror 9 reflects the laser light L11 and converts the direction of travel of the laser light L11 to a direction longitudinally rearward. The lens 10 condenses the laser light L11 and inputs the condensed laser light L11 to the modulator 11.

The modulator 11 has an approximately rectangular parallelepiped shape and is arranged such that a longitudinal direction of the modulator 11 is approximately in line with a longitudinal direction of the housing 1g. The modulator 11 modulates the laser light L11 to generate modulated light. The modulator 11 is a publicly known modulator that is, for example, a Mach-Zehnder (MZ) phase modulator using indium phosphide (InP) as a material to be included therein and that functions as an IQ modulator by being driven by the modulator driver 12. Such a phase modulator is similar to, for example, a phase modulator disclosed in International Publication No. WO 2016/021163. The modulator driver 12 is configured to include, for example, an IC, and operation thereof is controlled by the controller. The modulator 11 and the modulator driver 12 are arranged in series and approximately parallel to a length of the housing 1g and form a modulation unit M. The terminator 13 electrically terminates the modulator 11, to which a high frequency modulation signal is applied by the modulator driver 12.

The modulator 11 outputs modulated light L31 and modulated light L32 that are linearly polarized light beams having polarization planes orthogonal to each other and have each been subjected to IQ modulation. The modulator 11 has a turning structure, in which the direction of travel of light input thereto is turned around. As a result, in this modulator 11, an input position of the laser light L11 and output positions of the modulated light L31 and modulated light L32 are arranged on the same side surface of the modulator 11, the side surface being a side surface positioned longitudinally forward in this embodiment. This side surface of the modulator 11 and positioned longitudinally forward is approximately parallel to the side wall portion 1c of the housing 1g, the side wall portion 1c being longitudinally forward.

The lens 14 collimates the modulated light L31 and outputs the collimated modulated light L31 to the beam splitter 16. The beam splitter 16 reflects most of the modulated light L31 toward the polarization beam combiner 17 and transmits part of the modulated light L31 therethrough and outputs the transmitted part to the monitor PD 18. The lens 15 collimates the modulated light L32 and outputs the collimated modulated light L32 to the polarization beam combiner 17. The polarization beam combiner 17 generates output signal light L4 including the modulated light L31 and modulated light L32 by polarization combination of the modulated light L31 and modulated light L32. The polarization beam combiner 17 outputs part of the modulated light L32 to the monitor PD 19.

The monitor PD 18 receives the part of the modulated light L31 input from the beam splitter 16 and outputs an electric current signal corresponding to an intensity of the received light. The electric current signal is transmitted to the controller through the wiring pattern formed on the terminal portion 1f and is used for monitoring the intensity of the modulated light L31. The monitor PD 19 receives the part of the modulated light L32 input from the polarization beam combiner 17 and outputs an electric current signal corresponding to an intensity of the received light. The electric current signal is transmitted to the controller through the wiring pattern formed on the terminal portion 1f and is used for monitoring the intensity of the modulated light L32.

The beam splitter 20 transmits most of the output signal light L4 therethrough and reflects part of the output signal light L4 and outputs the reflected part to the monitor PD 21. The monitor PD 21 receives the part of the output signal light L4 input from the beam splitter 20 and outputs an electric current signal corresponding to an intensity of the received light. The electric current signal is transmitted to the controller through the wiring pattern formed on the terminal portion 1f and is used for monitoring the intensity of the output signal light L4.

The signal light output port 1a receives input of the output signal light L4 transmitted through the beam splitter 20 and outputs the output signal light L4 outside the housing 1g.

### Optical Receiver

Configurations and functions of components that function as an optical receiver will be described next.

The signal light input port 1b receives input of input signal light L5 from outside and outputs the input signal light L5 to the lens 30. The input signal light L5 travels in the housing 1g rearward from a longitudinally front end. The lens 30 condenses the input signal light L5 and inputs the condensed input signal light L5 to the coherent mixer 31.

The mirror 32 reflects the laser light L12 split by the beam splitter 8 and converts the direction of travel of the laser light L12 from a direction leftward widthwise to a direction longitudinally rearward. The laser light L12 is condensed by the lens 33 and is input as local light to the coherent mixer 31.

The coherent mixer 31 has an approximately rectangular parallelepiped shape and is arranged such that a longitudinal direction of the coherent mixer 31 is approximately in line with the longitudinal direction of the housing 1g. In this coherent mixer 31, an input position of the input signal light L5 and an input position of the laser light L12 are arranged on the same side surface of the coherent mixer 31, the side surface being a side surface positioned longitudinally forward in this embodiment. Furthermore, the side surface of the coherent mixer 31 is approximately parallel to the side wall portion 1c of the housing 1g, the side surface being where the input signal light L5 is input, the side wall portion 1c being longitudinally forward, and is approximately parallel to the side surface of the modulator 11, the side surface being where the input position of the laser light L11 and the output positions of the modulated light L31 and modulated light L32 are arranged.

The coherent mixer 31 performs processing by causing the laser light L12, which is the local light input, and the input signal light L5 to interfere with each other, generates processed signal light, and outputs the processed signal light to the balanced PD array 35. The processed signal light includes four signal light beams that are: an Ix signal light beam corresponding to an I component of X polarization, a Qx signal light beam corresponding to a Q component of X polarization, an Iy signal light beam corresponding to an I component of Y polarization, and a Qy signal light beam corresponding to a Q component of Y polarization. The coherent mixer 31 is a publicly known coherent mixer including, for example, a PLC. The coherent mixer 31 is configured to split off part of the input signal light L5 input and output the part split off to the monitor PD 34. The monitor PD 34 receives the part of the input signal light L5 and outputs an electric current signal corresponding to an intensity of the received light. The electric current signal is transmitted to the controller through the wiring pattern formed on the terminal portion 1f and is used for monitoring the intensity of the input signal light L5.

The balanced PD array 35 that is a photoelectric element has four balanced PDs and receives each of the four processed signal light beams, converts the four processed signal light beams into electric current signals, and outputs the electric current signals to the TIA 36. The TIA 36 has four TIAs and operation thereof is controlled by the controller. The TIAs that the TIA 36 has convert the electric current signals respectively input from the four balanced PDs into voltage signals and output the voltage signals. The output voltage signals are transmitted to the controller or a higher-order control device, through the wiring pattern formed on the terminal portion 1f and are used for demodulation of the input signal light L5.

The coherent mixer 31, the balanced PD array 35, and the TIA 36 are arranged in series and approximately parallel to the length of the housing 1g and form an optical processing unit OP.

The laser element 2a and the wavelength locker 4 in this optical device 1G are arranged, in a width direction of the housing 1g, between a widthwise center line CL1 of the coherent mixer 31 and a widthwise center line CL2 of the modulator 11. Being arranged between the widthwise center line CL1 and the widthwise center line CL2 also includes a state of being arranged between extension lines extended from these center lines longitudinally outside the coherent mixer 31 or the modulator 11. Furthermore, the modulator 11 has the turning structure, in which the direction of travel of light input thereto is turned around. Furthermore, the optical device 1G is configured such that optical axes of two light beams, the input signal light L5 and the laser light L2, intersect each other.

Furthermore, the laser element 2a and the wavelength locker 4 are arranged in series and approximately parallel to the length of the housing 1g and arranged such that an output position of the laser light L2 input to the wavelength locker 4 and an input position of the laser light L2 approximately coincide with each other widthwise in the housing 1g, the output position being on the laser element 2a, the input position being on the wavelength locker 4. Furthermore, the laser assembly LA, the modulation unit M, and the optical processing unit OP are arranged in the width direction of the housing 1g and in parallel. Furthermore, the input position of the laser light L11 and the output positions of the modulated light L31 and modulated light L32 are arranged on the same side surface of the modulator 11. Furthermore, this side surface and the side surface of the coherent mixer 31 are approximately parallel to each other, the side surface of the coherent mixer 31 being where the input signal light L5 is input. These two side surfaces are approximately parallel to the side wall portion 1c of the housing 1g, the side wall portion 1c being longitudinally forward.

In the optical device 1G configured as described above, a component having a width and a length that is wider than the width is able to be adopted for every one of components that are the laser element 2a, the wavelength locker 4, the modulator 11, and the coherent mixer 31, and arranging these components in parallel enables the housing 1g to have a width W of 15 mm or less, the width W being a widthwise size of the housing 1g. Furthermore, the optical device 1G enables its length to be 35 mm or less and its height to be 6.5 mm or less, the length being from a longitudinally rearmost point of the housing 1g to an optical reference plane where an end face of an optical fiber for input and output of optical signals abuts on. In a preferred example, the width W is about 14 mm, the length is about 31.5 mm, and the height is about 4 mm. An optical transceiver conforming to the QSFP-DD standard that is a next-generation standard under MSAs is thereby able to be implemented.

For a case where components are housed in separate housings like in an optical transceiver in Japanese Unexamined Patent Application, Publication No. 2001-021775, even if an optical transceiver is configured to have these components housed in a single housing, it is difficult for the optical transceiver to have a width of 15 mm or less. For example, under the CFP2-ACO standard, a micro-integrated tunable laser assembly (μITLA) that is a light source installed in an optical transceiver has a width of about 20 mm, a high bandwidth integrated polarization multiplexed quadrature modulator (HBPMQ) that is a modulator has a width of about 12.5 mm, and a micro-intradyne coherent receiver (μICR) that is a receiver has a width of about 12.5 mm, and even if an optical transceiver is configured to have these components housed in a single housing, it is difficult for the optical transceiver to have a width of 15 mm or less.

As illustrated in FIG. 13, this embodiment is configured to have the cube prism 100B1 as the mirror 9, the cube prism 100A1 as the beam splitter 16, the cube prism 100B1 as the polarization beam combiner 17, and the cube prism 100A1 as the mirror 32. Therefore, the embodiment achieves, similarly to the embodiments described above, an effect of enabling the optical device 1G to be configured smaller. This application example is just an example, and may be configured to have any other one of the prisms 100A and 100B and cube prisms 100A1 and 100B1 as the mirror 9, the beam splitter 16, the polarization beam combiner 17, or the mirror 32.

### Ninth Embodiment

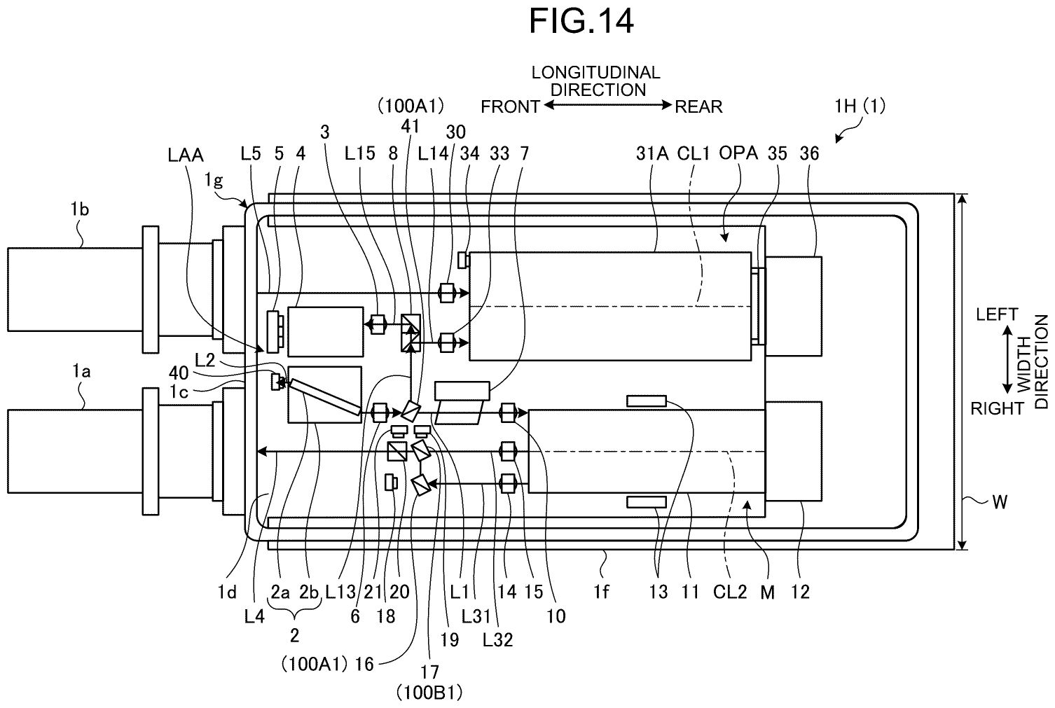

FIG. 14 is a plan view illustrating an internal configuration of an optical device 1H (1) according to a ninth embodiment. The optical device 1H has a configuration similar to that of the optical device 1G according to the eighth embodiment.

The optical device 1H has components housed therein, the components including: a chip-on-submount 2; a lens 3; a wavelength locker 4; a PD array 5; a lens 6; an optical isolator 7; a beam splitter 8; a lens 10; a modulator 11; a modulator driver 12; a terminator 13; lenses 14 and 15; a beam splitter 16; a polarization beam combiner 17; monitor PDs 18 and 19; a beam splitter 20; and a monitor PD 21. The optical device 1H has further components housed therein, the further components including: a lens 30; a coherent mixer 31A; a lens 33; a monitor PD 34; a balanced PD array 35; a transimpedance amplifier (TIA) 36; a monitor PD 40; and a beam splitter 41.

As to the components of the optical device 1H in contrast with the components of the optical device 1G, the mirror 32 has not been housed therein, the arrangement of the lens 30, the lens 33, and the monitor PD 34 has been changed, the coherent mixer 31 has been replaced by the coherent mixer 31A, and the monitor PD 40 and the beam splitter 41 have been added.

The optical device 1H has these components mounted in a housing 1g and an upper lid portion 1e is attached for hermetic sealing.

The optical device 1H is configured as an optical transceiver where output signal light is output from a signal light output port 1a and input signal light is input from a signal light input port 1b. Configurations and functions of the components will be described hereinafter.

### Optical Transmitter

Configurations and functions of components that function as an optical transmitter will be described first. Description of any component having the same configuration and functions as those of the optical device 1G will be omitted as appropriate.

The laser element 2a outputs laser light L1 longitudinally rearward in the housing 1g. Furthermore, the laser element 2a outputs laser light L2 for intensity monitoring longitudinally forward in the housing 1g. The monitor PD 40 receives the laser light L2 and outputs an electric current signal corresponding to an intensity of the received light. The electric current signal is transmitted to a controller through a wiring pattern formed in a terminal portion 1f and is used for intensity monitoring of the laser element 2a.

The lens 6 collimates the laser light L1 and outputs the collimated laser light L1 to the beam splitter 41. The beam splitter 41 transmits most of the laser light L1 therethrough toward the optical isolator 7, reflects part of the laser light L1, and outputs the reflected part as laser light L13 to the beam splitter 8.

The beam splitter 8 splits the laser light L13 into laser light L14 and laser light L15. The laser light L14 will be described in detail later.

The lens 3 condenses the laser light L15 and inputs the condensed laser light L15 to the wavelength locker 4. The wavelength locker 4 splits the laser light L15 into three parts, outputs one of the three parts to the PD array 5, and outputs the other two parts to the PD array 5 after allowing these other two beams respectively to pass through two filters.

Three PDs of the PD array 5 respectively receive the three parts of the laser light output by the wavelength locker 4 and output electric current signals corresponding to intensities of the received three parts of the laser light. The electric current signals are transmitted to the controller and are used for detection and control of wavelengths of the laser light L1.

The laser element 2a and the wavelength locker 4 are arranged in a width direction in parallel. Furthermore, the laser element 2a and the wavelength locker 4 are arranged such that an output position of the laser light L15 input to the wavelength locker 4, that is, an output position of the laser light L1, and an input position of the laser light L15 are different from each other widthwise, the output position being on the laser element 2a, the input position being on the wavelength locker 4. The laser element 2a and the wavelength locker 4 form a laser assembly LAA.

The optical isolator 7 transmits the laser light L1 therethrough and inputs the laser light L1 to the lens 10. The lens 10 condenses the laser light L11 and inputs the condensed laser light L1 to the modulator 11.

The modulator 11 is arranged such that a longitudinal direction of the modulator 11 is approximately in line with a longitudinal direction of the housing 1g. The modulator 11 functions as an IQ modulator by being driven by the modulator driver 12. Operation of the modulator driver 12 is controlled by the controller. The modulator 11 and the modulator driver 12 are arranged in the longitudinal direction of the housing 1g in series and form a modulation unit M. The terminator 13 electrically terminates the modulator 11.

The modulator 11 outputs modulated light L31 and modulated light L32 that have each been subjected to IQ modulation. The modulator 11 has a turning structure. As a result, in the modulator 11, an input position of the laser light L1 and output positions of the modulated light L31 and modulated light L32 are arranged on the same side surface of the modulator 11, the side surface being positioned longitudinally forward. This side surface of the modulator 11 and positioned longitudinally forward is approximately parallel to a side wall portion 1c of the housing 1g, the side wall portion 1c being longitudinally forward.

Configurations and functions of the lens 14, beam splitter 16, lens 15, polarization beam combiner 17, monitor PDs 18 and 19, and beam splitter 20 are the same as the configurations and functions of the corresponding components of the optical device 1G and description thereof will thus be omitted.

The signal light output port 1a receives input of output signal light L4 transmitted through the beam splitter 20 and outputs the output signal light L4 outside the housing 1g.

### Optical Receiver

Configurations and functions of components that function as an optical receiver will be described next.

The signal light input port 1b receives input of input signal light L5 from outside and outputs the input signal light L5 to the lens 30. The lens 30 condenses the input signal light L5 and inputs the condensed input signal light L5 to the coherent mixer 31.

The laser light L14 split by the beam splitter 8 is condensed by the lens 33 and is input as local light to the coherent mixer 31A.

The coherent mixer 31A has an approximately rectangular parallelepiped shape and is arranged such that a longitudinal direction of the coherent mixer 31A is approximately in line with the longitudinal direction of the housing 1g. In this coherent mixer 31A, an input position of the input signal light L5 and an input position of the laser light L14 are arranged on the same side surface of the coherent mixer 31A, the side surface being positioned longitudinally forward. The side surface of the coherent mixer 31A, the side surface being where the input signal light L5 is input, is approximately parallel to the side wall portion 1c of the housing 1g, the side wall portion 1c being longitudinally forward, and is approximately parallel to the side surface of the modulator 11, the side surface being where the input position of the laser light L1 and the output positions of the modulated light L31 and modulated light L32 are arranged.

Similarly to the coherent mixer 31, the coherent mixer 31A generates four processed signal light beams and outputs the four processed signal light beams to the balanced PD array 35. The coherent mixer 31A is configured to split off part of the input signal light L5 input and output the part to the monitor PD 34. The monitor PD 34 is used for monitoring intensity of the input signal light L5.

Configurations and functions of the balanced PD array 35 and TIA 36 are the same as the configurations and functions of the corresponding components of the optical device 1G and description thereof will thus be omitted.

The coherent mixer 31A, the balanced PD array 35, and the TIA 36 are arranged in series and approximately parallel to a length of the housing 1g and form an optical processing unit OPA.

The laser element 2a in this optical device 1H is arranged in the housing 1g to output the laser light L1 in a direction (longitudinally rearward) opposite to a direction (longitudinally forward) where the signal light output port 1a has been provided. Furthermore, the laser element 2a and the wavelength locker 4 are arranged in a width direction of the housing 1g, between a widthwise center line CL1 of the coherent mixer 31A and a widthwise center line CL2 of the modulator 11. Furthermore, the modulator 11 has the turning structure, in which the direction of travel of light input thereto is turned around.

Furthermore, the laser element 2a and the wavelength locker 4 are arranged such that the output position of the laser light L15 (laser light L1) input to the wavelength locker 4 and the input position of the laser light L15 are different from each other widthwise, the output position being on the laser element 2a, the input position being on the wavelength locker 4. Furthermore, the modulation unit M and the optical processing unit OPA are arranged in the width direction of the housing 1g in parallel. Furthermore, the input position of the laser light L11 and the output positions of the modulated light L31 and modulated light L32 are arranged on the same side surface of the modulator 11. Furthermore, this side surface and the side surface of the coherent mixer 31A are approximately parallel to each other, the side surface of the coherent mixer 31A being where the input signal light L5 is input. These two side surfaces are also approximately parallel to the side wall portion 1c of the housing 1g, the side wall portion 1c being longitudinally forward.

In the optical device 1H configured as described above, the wavelength locker 4 does not need to be arranged on the same longitudinal axis as the laser element 2a. Therefore, while adopting the same kind of component larger widthwise than the component adopted in the optical device 1G (for example, the coherent mixer 31A corresponding to the coherent mixer 31), a length from the longitudinally rearmost point of the housing 1g to an optical reference plane is able to be made 35 mm or less and a height is able to be made 6.5 mm or less, with a width W maintained at 15 mm or less, the width W being a widthwise size of the housing 1g. An optical transceiver conforming to the QSFP-DD standard that is a next-generation standard under MSAs is thereby able to be implemented.

As illustrated in FIG. 14, this embodiment is configured to have the cube prism 100A1 as the beam splitter 16, the cube prism 100B1 as the polarization beam combiner 17, and the cube prism 100A1 as the beam splitter 41. Therefore, the embodiment achieves, similarly to the embodiments described above, an effect of enabling the optical device 1H to be configured smaller. This application example is just an example, and may be configured to have any other one of the prisms 100A and 100B and cube prisms 100A1 and 100B1 as the beam splitter 16, the polarization beam combiner 17, or the beam splitter 41.

Examples of embodiments of the present disclosure have been described above, but the embodiments described above are just examples and are not intended to limit the scope of the disclosure. The above described embodiments may be implemented in various other modes, and without departing from the gist of the disclosure, various omissions, substitutions, combinations, and modifications may be made. Furthermore, they may be implemented by modifying, as appropriate, the specifications of the components and shapes (such as, the structures, types, directions, models, sizes, lengths, widths, thicknesses, heights, numbers, arrangements, positions, and materials), for example.

The present disclosure enables obtainment of a prism and an optical device that are novel and improved and that enable further downsizing, for example.

What is claimed is:

1. A prism comprising:
an incidence plane that is a plane extending in a first direction and is where light is input to;
a reflection plane that is a plane extending in the first direction and is where at least part of the light that has been input to the incidence plane is reflected; and
an output plane that is a plane extending in the first direction and is where the at least part of the light reflected by the reflection plane is output from, wherein
the incidence plane, the reflection plane, and the output plane respectively extend in directions intersecting the first direction and different from one another,
the prism changes a direction of travel of light approximately along a virtual plane orthogonal to the first direction and has a refractive index of n where n>1, and
in a case where the prism is viewed in the first direction,
an angular difference between the incidence plane and the output plane is 90 degrees,
the light input to the incidence plane travels in a second direction,
the incidence plane extends to be directed more in the second direction from a position where the light is input, toward the output plane, and
the following Expression 1 is satisfied when an angular difference between a virtual plane orthogonal to the second direction and the incidence plane is θ where θ>0 degrees and an angular difference between the output plane and the reflection plane is x degrees.
$$45 < x < 45 + 2 θ / n \qquad ( 1 )$$

2. The prism according to claim 1, the prism satisfying the following Equation 1-1.
$$X = 45 + θ / n \qquad ( 1 - 1 )$$

3. The prism according to claim 1, wherein the reflection plane transmits part of light from the incidence plane therethrough.

4. The prism according to claim 3, further comprising a filter that transmits light having a predetermined wavelength therethrough, the light being from the part of light that has been transmitted through the reflection plane.

5. An optical device, comprising:
the prism according to claim 1;
an optical component where the light output from the output plane is input to or travels through; and
a base where the prism and the optical component are fixed to.

6. The optical device according to claim 5, wherein the prism includes a first prism, and a second prism where light output from the first prism is input to.

7. A prism comprising:
an incidence plane that is a plane extending in a first direction and is where light is input to;
a reflection plane that is a plane extending in the first direction and is where at least part of the light that has been input to the incidence plane is reflected; and
an output plane that is a plane extending in the first direction and is where the at least part of the light reflected by the reflection plane is output from, wherein
the incidence plane, the reflection plane, and the output plane respectively extend in directions intersecting the first direction and different from one another,
the prism changes a direction of travel of light approximately along a virtual plane orthogonal to the first direction and has a refractive index of n where n>1, and
in a case where the prism is viewed in the first direction,
an angular difference between the incidence plane and the output plane is 90 degrees,
the light input to the input plane travels in a second direction,
the incidence plane extends to be directed more in a direction opposite to the second direction from a position where the light is input, toward the output plane, and
the following Expression 2 is satisfied when an angular difference between a virtual plane orthogonal to the second direction and the incidence plane is θ where θ>0 degrees and an angular difference between the output plane and the reflection plane is y degrees.
$$45 - 2 θ / n < y < 45 \qquad ( 2 )$$

8. The prism according to claim 7, the prism satisfying the following Equation 2-1.
$$y = 45 - θ / n \qquad ( 2 - 1 )$$

9. The prism according to claim 7, wherein the reflection plane transmits part of light from the incidence plane therethrough.

10. The prism according to claim 9, further comprising a filter that transmits light having a predetermined wavelength therethrough, the light being from the part of light that has been transmitted through the reflection plane.

11. An optical device, comprising:
the prism according to claim 7;
an optical component where the light output from the output plane is input to or travels through; and
a base where the prism and the optical component are fixed to.

12. The optical device according to claim 11, wherein the prism includes a first prism, and a second prism where light output from the first prism is input to.
